(19) United States
(12) Patent Application Publication
(10) Pub. No.: US 2016/0205808 A1
(43) Pub. Date: Jul. 14, 2016

(54) DEVICE FOR COOLING A COMPUTER WITH A CLASP ELEMENT

(71) Applicant: Hardware Labs Performance Systems, Inc., Quezon City (PH)

(72) Inventor: Wilbert Yuque, Quezon City (PH)

(73) Assignee: HARDWARE LABS PERFORMANCE SYSTEMS, INC., Quezon City (PH)

(21) Appl. No.: 14/833,872

(22) Filed: Aug. 24, 2015

(30) Foreign Application Priority Data
Jan. 8, 2015 (DE) 10 2015 000 239.2

(51) Int. Cl. H05K 7/20; F16B 2/22; F16M 13/02

(52) U.S. Cl. CPC H05K 7/20263; F16M 13/022; F16B 2/22

(57) ABSTRACT

The invention relates to a device for cooling and/or heating a computer housing interior with at least one fan and a heat exchanger. The fan can be permanently attached to the computer housing and creates a fluid flow into or out of the housing. The heat exchanger is removably coupled to the fan by one or more clasps. The clasps are fixedly coupled to the fan and include an elastically deformable holding section that engages a recess on the heat exchanger to retain the heat exchanger in a form-fitting manner on the fan.

### CROSS-REFERENCE TO RELATED APPLICATIONS

This application claims the benefit of German Patent Application No. 10 2015 000 239.2, filed Jan. 8, 2015 the disclosure of which is hereby incorporated herein in its entirety by reference.

### BACKGROUND

Individual components of fan/heat-exchanger combinations used in computer housings are often interconnected in a relatively complex manner. In order to separate the components from each other, such as during the cleaning of the heat exchanger or fan, usually several fastening means designed as screws need to be released in a complex manner and the entire device first needs to be removed from the computer housing. Separate tools are often needed to release the connection.

An exemplary embodiment of the state of the art is disclosed in DE 203 09 986 U1, wherein a device for cooling electronic components in an electronic device is described. Among other things, the device comprises a cooling body with air-cooled cooling fins in the sense of a heat exchanger and with a water cooling circuit with cool water pump, wherein the electronic components to be cooled are integrated in the water cooling circuit. The cooling body is designed as a one-piece extruded profile part and designed as a plug-in part for processor slots.

DE 203 09 986 U1 thus also shows a relatively complex assembly of a cooling body with a fan.

A cooling and/or heating device that can be removed by a computer user in a simple manner and that is also particularly simple to clean would be beneficial to users in the art.

### SUMMARY

Embodiments of the invention are defined by the claims below, not this summary. A high-level overview of various aspects of the invention is provided here to introduce a selection of concepts that are further described in the Detailed-Description section below. This summary is not intended to identify key features or essential features of the claimed subject matter, nor is it intended to be used in isolation to determine the scope of the claimed subject matter. In brief, this disclosure describes, among other things, a device for mounting a computer heat exchanger.

The heat exchanger includes at least one fan that can be permanently or fixedly attached to a computer housing for creating a fluid flow (in an operating state) and with a heat exchanger influencing and/or adjusting the temperature of the fluid flow. The heat exchanger is connected in a non-destructively removable manner with the at least one fan, e.g. the heat exchanger is removable from the fan without destroying or damaging the heat exchanger and the fan. The device is thus also called a fan/heat exchanger combination system or an acclimatization device. The invention also relates to a computer housing with such a device, an electronic processing unit with the computer housing, and a clasp element.

According to embodiments of the invention, the heat exchanger is held or fastened in a form-fitting manner on the fan by means of at least one clasp element. Such a form-fitting connection has the effect that the heat exchanger can be easily released from the fan, i.e. without the use of separate tools. The cleaning of the device components, in particular the heat exchanger and the fan is thereby considerably simplified.

According to a further embodiment, it is advantageous if the at least one clasp element has a disk-shaped or plate-shaped base section, which is fastened on the at least one fan. The clasp element between the fan and the heat exchanger thereby uses as little installation space as possible. The base section also preferably has at least one fastening means receiver designed as a through hole, into which the fastening means connecting the clasp element with the fan is inserted. A particularly strong connection of the clasp element to the fan may thus be realized. The fastening means may comprise a screw or rivet, for example a self-tapping screw or rivet. A particularly strong connection is thereby realized.

In this connection, it is also advantageous if the base section has a centrally arranged fluid through hole. Thereby, the at least one clasp element does not influence or influences only slightly the fluid flow generated by the fan during operation of the device. A particularly efficient supply of fluid to the heat exchanger is thereby ensured.

It is also advantageous if the at least one clasp element has at least one elastically deformable holding section, which engages/locks into a recess of the heat exchanger in a form-fitting manner. The heat exchanger can thereby be removed from and repositioned on the clasp element or respectively the fan any number of times. The ease of maintenance is thereby further increased.

It is also advantageous if the at least one holding section has a snap bar, a snap catch and/or a snap finger, whereby the clasp element can be made in a particularly simple manner, preferably of sheet metal or of plastic by means of an injection-molding process.

The at least one clasp element may have at least two of the elastically deformable holdings sections (e.g. a first holding section and a second holding section), which are arranged on opposite edge areas of the clasp element and surround/enclose the heat exchanger in a form-fitting manner in the operating state. In another embodiment, at least two, preferably three or four, clasp elements are fastened on the fan, each of which form one of the elastically deformable holding sections. At least two clasp elements are respectively arranged on opposite lateral edge areas of the heat exchanger and are received/held on it in a form-fitting manner. A particularly stable holding of the heat exchanger may thereby be realized.

In an embodiment, the at least one clasp element is made of a metal, preferably a sheet metal. The sheet metal is further preferably shaped by means of die-cut and/or cold forming processes. Production is thereby particularly cost-effective and the clasp element is particularly durable. In another embodiment, the at least one clasp element is comprised of a plastic material so that the at least one clasp element is then advantageously shaped entirely by means of an injection-molding process. The at least one clasp element can then be shaped in a cost-effective manner.

If the fan has a fastening section/contact area, which is prepared for fastening to a computer housing, the fan is already ready to use in a computer/computer housing.

In an embodiment, the at least one clasp element is compatible several fold, for example two-, three- or four-fold, i.e. that the at least one clasp element is designed to receive several, namely two, three or four fans. Several fans can thus be arranged/held/fastened in series next to each other on the base section of the at least one clasp element. The cooling capacity is thereby further improved.

Embodiments of the invention may include a computer housing with a device according to at least one of the aforementioned embodiments, wherein the fan is then fastened/attached to an outer wall (of the computer housing) in the area of a fluid inlet opening. It is preferable to place the fan with its stator placed directly on the fluid inlet opening so that a direct fluid conveyance through the computer housing into the fan is realized. A computer housing is thereby provided with increased ease of cleaning.

Embodiments of the invention may also include an electronic processing unit (i.e. a computer/PC) with such a computer housing, whereby the electronic components of the electronic processing unit are acclimatized in a particularly effective manner.

Furthermore, embodiments of the invention also relate to the at least one clasp element itself according to one of the aforementioned embodiments, as it is used in one of the aforementioned devices, wherein the at least one clasp element has at least one receiving area, which is designed/prepared for fastening on a fan and has at least one elastically deformable holding section for the form-fitting receiving of a heat exchanger. A versatile clasp element is thereby realized.

### DESCRIPTION OF THE DRAWINGS

Illustrative embodiments of the invention are described in detail below with reference to the attached drawing figures, and wherein:

FIG. 1 is an edge perspective view of a device for cooling and/or heating a computer housing interior with a clasp element fastened on the fan side using fastening means and attached on the heat exchanger side using a form fit depicted in accordance with an embodiment of the invention;

FIG. 2 is an edge perspective view of the device of FIG. 1 depicting the fan and clasp element detached from the heat exchanger in accordance with an embodiment of the invention;

FIG. 3 is a side perspective view of the fan and clasp of FIG. 1;

FIG. 4 is an exploded edge perspective view of the fan and clasp of FIG. 3;

FIG. 5 is a side perspective view of the clasp element of FIG. 1 alone

FIG. 6 is a perspective view of a computer housing with the device of FIG. 1 fastened on an interior surface of the housing in accordance with an embodiment of the invention;

FIG. 7 is an exploded view of the computer housing, the clasp, the fan, and the heat exchanger of FIG. 6, the computer housing being depicted without a fluid inlet opening for clarity;

FIG. 8 is a partially exploded view of the computer housing of FIG. 7, wherein the fan/clasp element pre-assembly, of FIG. 4, is fastened on the wall of the computer housing, but the heat exchanger is still removed from the clasp element and is moved toward it;

FIG. 9 is an edge perspective view of a fan/clasp element pre-assembly in which the clasp element is designed to receive two fans arranged next to each other depicted in accordance with an embodiment of the invention;

FIG. 10 is an edge perspective view of a fan/clasp element pre-assembly in which the clasp element is designed to receive three fans arranged next to each other;

FIG. 11 is an edge perspective view of a fan/clasp element pre-assembly in which the clasp element is designed to receive four fans arranged next to each other on the clasp element;

FIG. 12 is a perspective view of a clasp element depicted in accordance with an embodiment of the invention;

FIG. 13 is a perspective view of four clasp elements designed according to the embodiment depicted in FIG. 12 for fastening on a fan, wherein the clasp elements are depicted arranged relative to each other such as they would be positioned in the installed state with two clasp elements to each side edge area of a heat exchanger;

FIG. 14 is an exploded perspective view of a fan with the clasp elements of FIG. 13 depicted in accordance with an embodiment of the invention;

FIG. 15 is a partially exploded perspective view of the fan/clasp element of FIG. 14, wherein the clasp elements with their base sections rest on the stator of the fan;

FIG. 16 is a perspective view of the fan/clasp element of FIGS. 14 and 15, depicting the clasp elements attached to the stator of the fan by fastening means;

FIG. 17 is a perspective view of an opposite side of the installed fan/clasp element shown in FIG. 15;

FIG. 18 is another perspective view of the fan/clasp element of FIG. 15;

FIG. 19 is an edge elevational view of the fan/clasp element of FIGS. 15 to 18;

FIG. 20 is an exploded perspective view of a computer housing (shown without a fluid inlet opening) depicting the fan/clasp element of FIGS. 16 to 18 and a heat exchanger;

FIG. 21 is a perspective view of the computer housing of FIG. 20 depicting the device in an installed state and fastened on the housing in accordance with an embodiment of the invention;

FIG. 22 is a perspective view of a clasp element with stop catches that may be placed on the stator of the fan depicted in accordance with another embodiment of the invention;

FIG. 23 is a perspective view of four of the clasp elements of FIG. 22 for fastening on a fan, wherein the clasp elements are depicted arranged with respect to each other as they would be positioned relative to each other when installed on the fan;

FIG. 24 is a perspective view of a fan/clasp element pre-assembly comprising the four clasp elements of FIG. 23, wherein the clasp elements are connected with the stator of the fan by fastening means depicted in accordance with an embodiment of the invention;

FIG. 25 is an exploded perspective view of a computer housing with the fan/clasp element pre-assembly of FIG. 24 spaced from a wall of the computer housing and a heat exchanger that is not yet in form-fitting engagement in the clasp elements depicted in accordance with an embodiment of the invention;

FIG. 26 is a partially exploded perspective view of the computer housing of FIG. 25, wherein now the fan/clasp element pre-assembly is attached to the wall of the computer housing and the heat exchanger is moved in the direction of the clasp elements towards the clasp elements for form-fitting connection with the fan;

FIG. 27 is a perspective view of the computer housing of FIGS. 25 and 26, wherein the heat exchanger is held in a form-fitting manner by the clasp elements;

FIG. 28 a perspective view of a pair of clasp elements arranged next to each other and each clasp element has a mainly bar-like shape, wherein the base section is in turn connected with a holding section configured as a snap bar;

FIG. 29 is a perspective view of a fan/clasp element pre-assembly that includes the clasp element depicted in FIG. 28;

FIG. 30 is an exploded perspective view of a computer housing, depicted without a fluid inlet opening for clarity, with the fan/clasp element pre-assembly of FIG. 29 and a heat exchanger depicted in accordance with an embodiment of the invention;

FIG. 31 is a partially exploded perspective view of the computer housing of FIG. 24 wherein the fan/clasp element pre-assembly of FIG. 29 is fastened on a wall of the computer housing, but the heat exchanger has not yet been received in the clasp elements in a form-fitting manner; and

FIG. 32 is a perspective view of the computer housing of FIGS. 30 and 31 depicting the fan/clasp pre-assembly and heat exchanger in an installed state and fastened on the computer housing so that the heat exchanger is held by the clasp elements in a form-fitting manner on the fan and is thus held on the wall of the housing.

### DETAILED DESCRIPTION

The subject matter of select embodiments of the invention is described with specificity herein to meet statutory requirements. But the description itself is not intended to necessarily limit the scope of claims. Rather, the claimed subject matter might be embodied in other ways to include different components, steps, or combinations thereof similar to the ones described in this document, in conjunction with other present or future technologies. Terms should not be interpreted as implying any particular order among or between various steps herein disclosed unless and except when the order of individual steps is explicitly described.

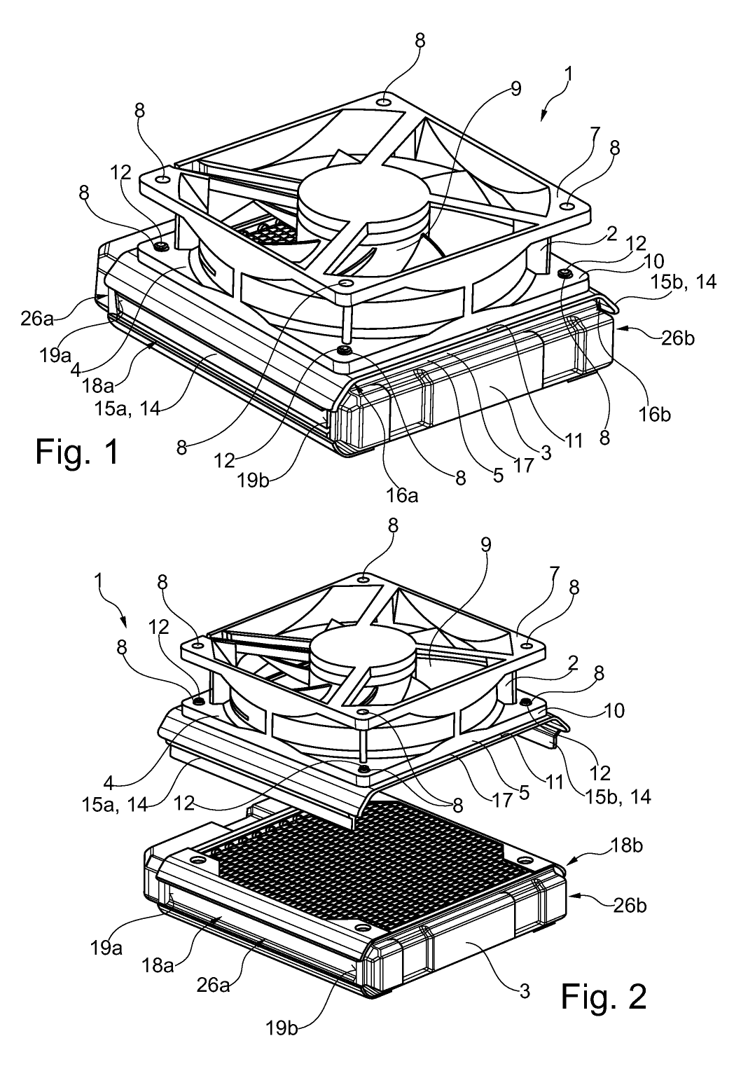

FIG. 1 shows a device 1 for cooling or heating, i.e. acclimatizing a computer housing interior, which is also called acclimatization device below in accordance with an embodiment of the invention. In the exemplary embodiments shown, the device 1 comprises a fan 2 that can be permanently attached to a computer housing 6 (FIG. 6), i.e. having means for fastening on a computer housing 6. The fan 2 is provided in a conventional manner to generate a fluid flow, to direct the fluid flow in the operating state of a computer into or out of the inside of a computer housing 6 and/or the computer housing interior 22. Moreover, the device 1 has a heat exchanger 3 that cools or heats the fluid flow produced by the fan depending on the switching status, i.e. removes or adds heat to the fluid flow. The heat exchanger 3 may be a lamella heat exchanger. The heat exchanger 3 is connected in a removable manner with the fan 2 and is namely fastened or held in a form-fitting manner on the fan 2 according to embodiments of the invention by means of a clasp element 5.

According to the embodiment according to FIG. 1, the device 1 is designed as an acclimatization device 1, which cools the fluid flow in a first switching status of the heat exchanger 3 (i.e. removes thermal energy from it) and heats it in a second switching status of the heat exchanger 3 (i.e. feeds thermal energy to it). In a further embodiment, the device 1 is designed as a cooling device, whereby the heat exchanger 3 is only operated or operable in one state, namely in which it cools the fluid flow. In another embodiment, the device 1 is exclusively designed to heat the computer housing interior 22, i.e. as a heating device.

The fan 2 has in the conventional manner a stator 4, which is prepared for fastening on the computer housing 6 as is explained in greater detail below. For this, the stator 4 (also called the housing of the fan 2 or fan housing) has on a first front side an even, plate-like, first contact area 7, e.g. a first fastening section. The first contact area 7 includes several (four as shown) fastening means receivers 8. In the fastened state of the device 1 on a computer housing 6, the fastening means receivers 8 are penetrated by several fastening means in the form of screws, or alternatively as rivets or the like, wherein the fastening means simultaneously engage in an outer wall 21 of the computer housing 6.

In turn, a rotor 9 receiving several feed shovels is rotatably arranged within the stator 4. The rotor 9 is mounted and drivable in the conventional manner for conveying a fluid flow in the direction of the heat exchanger 3 in a rotary manner relative to the stator 4. On a side facing the clasp element 5 or respectively the heat exchanger 3, the stator 4 in turn has a second contact area 10 or a second fastening section, which lies in a planar manner on a first contact surface 11 of the clasp element 5.

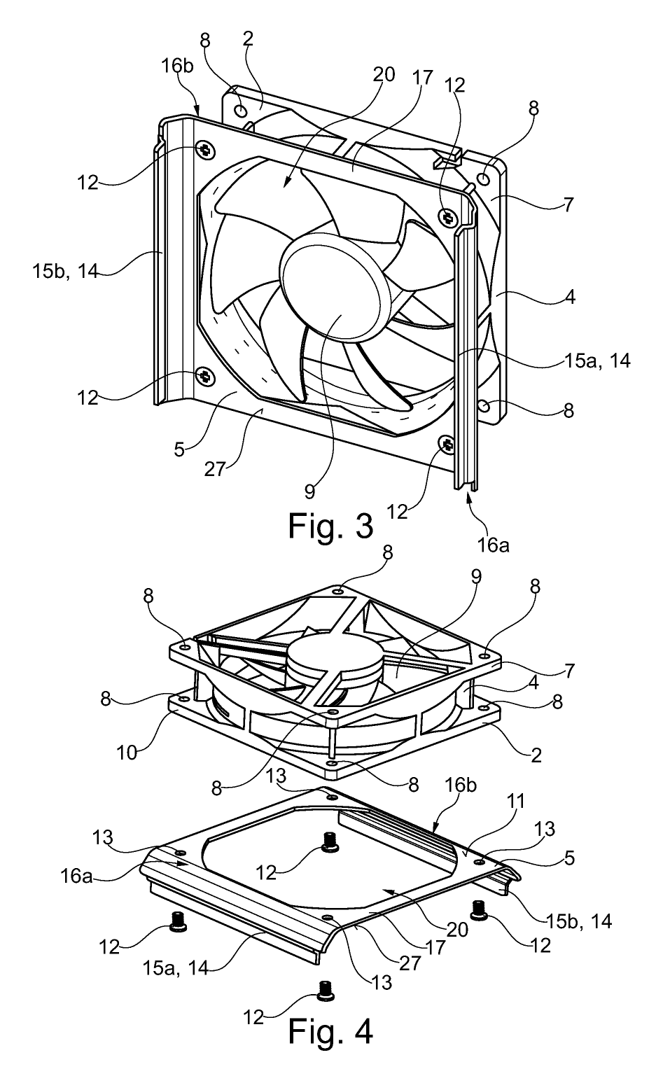

As shown in FIG. 4, this second contact area 10 also has several (e.g. four) fastening means receivers 8, which in turn serve to receive fastening means 12. The fastening means 12 are designed in the form of self-tapping screws. But, in another embodiment, it is also possible to design the fastening means as a rivet, self-tapping rivet or threaded rivet. In the fastened state depicted in FIG. 1, the fastening means 12 press the clasp element 5 with its first contact surface 11 of its disk-shaped base section 17 onto the second contact area 10 of the stator 4 (FIG. 3) so that the clasp element 5 is permanently or fixedly connected with the stator 4. For receiving the fastening means 12 connecting the clasp element 5 with the stator 4 in a force- and form-fitting manner, the clasp element 5 in turn has several, namely four, fastening means receivers 13 in the form of through holes. The combination or coupling of the fan 2/stator 4 with the clasp element 5 is referred to hereinafter as a fan/clasp element pre-assembly.

With reference now to FIGS. 2-3, and 5-6, the form-fitting connection between the clasp element 5 and the heat exchanger 3 is shown. For example, it is shown in FIG. 3 that the clasp element 5 includes two parallel snap bars 14. Each of the two snap bars 14 forms an elastically deformable holding section 15a, 15b. The holding sections 15a, 15b are integrally shaped respectively on an edge area 16a and 16b on the disk-shaped base section 17 of the clasp element 5. The two holding sections 15a and 15b extend in a direction, as seen in the axial direction of the fan 2 (axial direction of the fan 2 corresponds with the flow direction of the fluid flow), away from fan 2. The longitudinal axes of the bar-shaped holding sections 15a and 15b progress mainly parallel to the extension plane of the base section 17.

Each holding section 15a and 15b is assigned to a recess 18a or respectively 18b on the heat exchanger 3 or respectively on the outside of the housing of the heat exchanger. As shown in FIG. 2, the heat exchanger 3 includes an elongate extending recess 18a, 18b progressing in a generally straight line on respectively one lateral edge area 26a and 26b. FIG. 2 depicts the first recess 18a on a first lateral edge area 26a, wherein the second recess 18b is shown on a second lateral edge area 26b facing away from this first lateral edge area 26a. The length of the first recess 18a generally corresponds with the length of the first holding section 15a of the clasp element 5, wherein the first holding section 15a is preferably designed slightly shorter than the first recess 18a so that a clearance fit between the first holding section and the first recess 18a is realized in the installed state. The length of the second recess 18a indicated in FIG. 2 also corresponds with the length of the second holding section 15b wherein the second holding section 15a is designed in turn slightly shorter than the second recess 18a so that a clearance fit between the second holding section 15b and the second recess 18b is realized in the installed state.

In the installed state shown in FIG. 1, the two holding sections 15a and 15b are held pre-tensioned respectively elastically away from each other to lock the holding sections 15a and 15b in the respective recesses 18a, 18b in a snap-fit manner. The heat exchanger 3 lies in a planar manner on a second contact surface 27 facing away from the first contact surface 11. While the clasp element 5 is being pushed onto the heat exchanger 3, the holding sections 15a and 15b are elastically deformed or pretensioned through a pressing apart of the holding sections 15a and 15b. After this expansion, the holding sections 15a and 15b snap into the respective recess 18a, 18b so that the clasp element 5 is then connected in a form-fitting manner with the heat exchanger 3. Moreover, a stop edge 19a or respectively 19b is connected in the longitudinal direction of each recess 18a and 18b, which geometrically delimits the recesses 18a and 18b in the longitudinal direction. The holding sections 15a and 15b lie in the installed state of the heat exchanger 3 both in the longitudinal direction as well as in the transverse direction of the recess 18a and 18b in a non-displaceable manner on the heat exchanger 3 through contact on the stop edges 19a or respectively 19b. A particularly secure, form-fitting holding of the heat exchanger 3 is thereby realized.

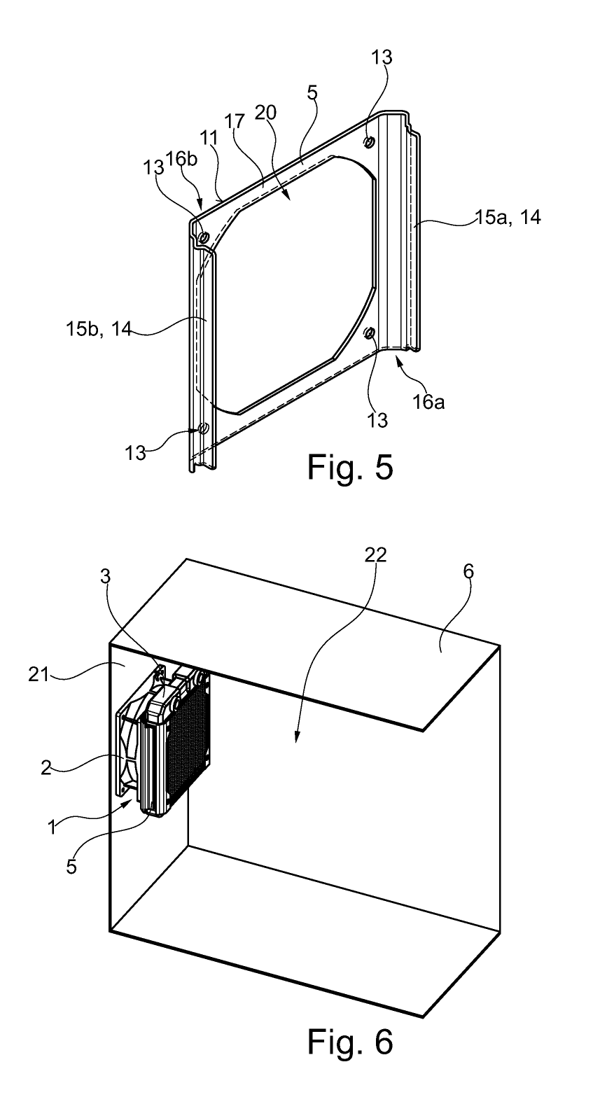

As shown by FIG. 5, the disk-shaped base section 17 of the clasp element 5 is provided with a central fluid through hole 20, which connects to the rotor 9 in the installed state seen with respect to the fluid flow.

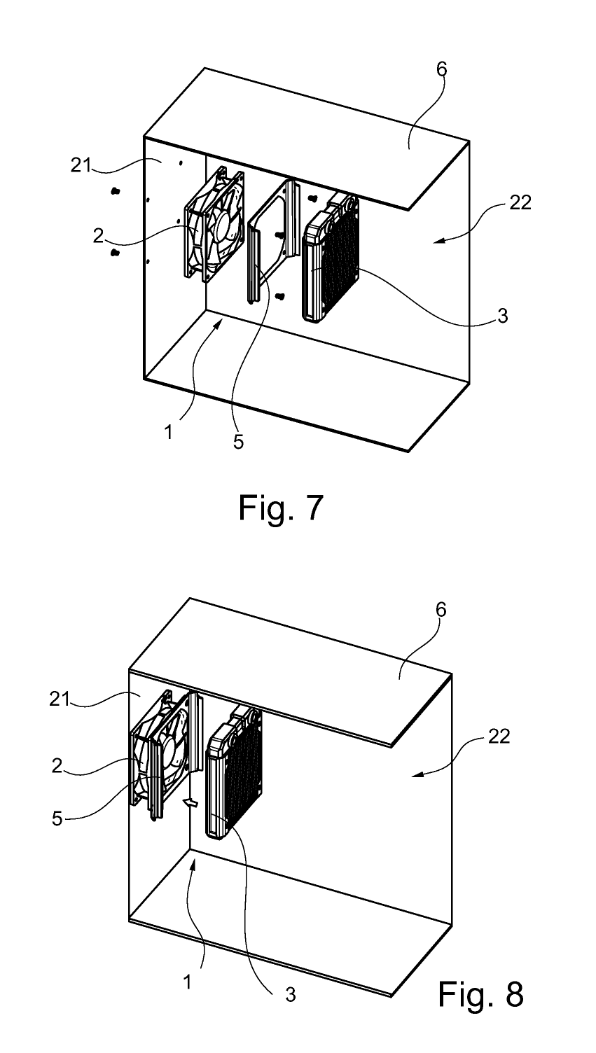

In the operating state of the device 1, the fan 2 is fastened on the wall or outer wall 21 of the computer housing 6, namely on an inside, i.e. a side of the wall 21 facing the computer housing interior 22 as depicted in FIGS. 6-8. The fan 2 is thereby fixedly connected with the computer housing and the heat exchanger 3 is removable for cleaning only by loosening the elastically deformable holding sections 15a and 15b forming the form-fitting connection so that a simple removal without tools is realizable. As shown in FIG. 7, the fan/clasp element pre-assembly is fastened on the outer wall 21 by means of several fastening means (screws), the heat exchanger 3 is pushed onto the clasp element 5, from a side facing away from the fan 2 (FIG. 8), until finally the holding sections 15a, 15b/snap bars 14 of the clasp element 5 lock into the heat exchanger 3 in a form-fitting manner (FIG. 6).

Moreover, as depicted in FIG. 5, the clasp element 5 may be designed with a thin wall. In this embodiment, the clasp element 5 is made of a metal material, namely a sheet metal. The holding sections 15a and 15b are thereby preferably respectively designed by means of a cold forming process, for example by means of a bending and/or deep-drawing process. The fluid through hole 20 is also preferably die-cut. The fastening means receivers 13 may also be produced using die-cutting, or alternatively by means of a tensioning process, such as a drilling process. According to a further embodiment, the clasp element 5 may be made of a plastic material, namely by means of a plastic injection-molding process. According to a further advantageous embodiment, the first or respectively second holding sections 15a and 15b also have one or more snap fingers or snap catches 24 instead of a snap bar.

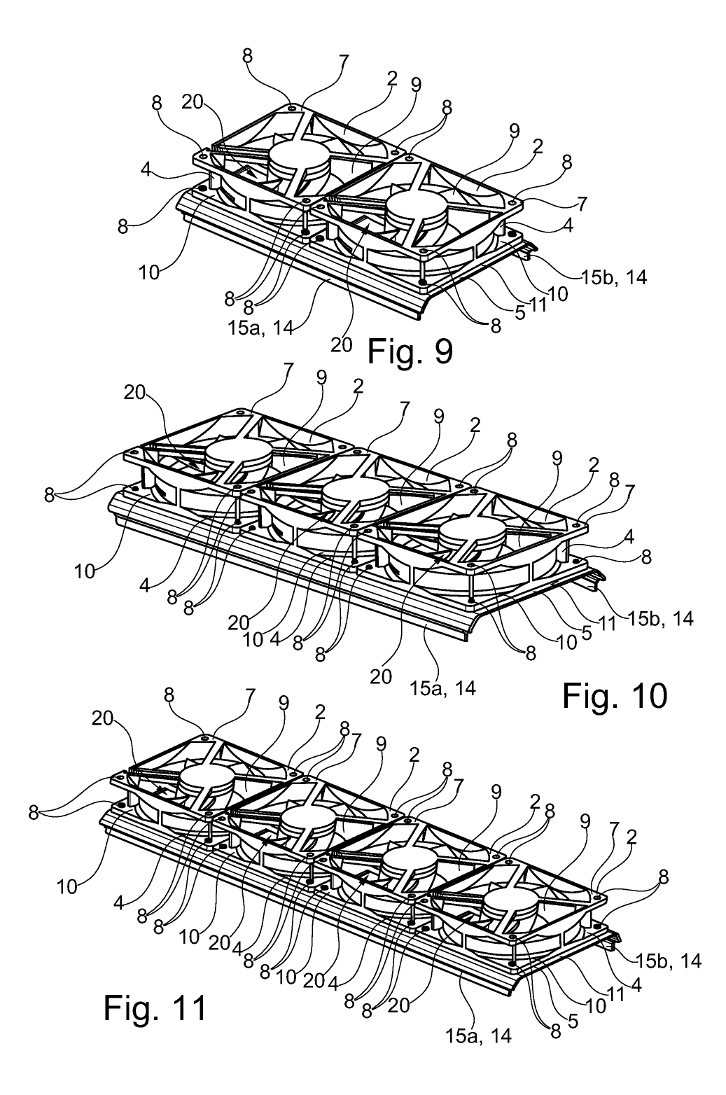

In FIG. 9-11, three additional embodiments of the assembly made up of fan 2 and clasp element 5 (i.e. the fan/clasp element pre-assembly) are shown. As shown in FIG. 9, the clasp element may be designed such that it mainly has two fluid through holes 20 arranged next to each other, wherein a separate fan 2 is assigned to each fluid through hole 20. The clasp element is thus no longer compatible once (according to the first embodiment) but compatible twice. As a result, the clasp element 5 is then also connected by means of two fans 2 in the aforementioned manner.

According to further embodiments depicted in FIG. 10, it is also possible to fasten three or, according to FIG. 11, even four fans 2 to a clasp element 5 having three or four fluid through holes 20, respectively. The clasp element 5 is thereby also compatible three- or four-fold. The cooling or respectively heating power is then further improved. Although particular embodiments are depicted herein, the clasp element 5 may be configured for any number of fans 2.

According to FIG. 6, the invention not only relates to the device 1 or respectively the clasp element 5 in general, but also to a computer or respectively a computer housing 6 of the computer with this device 1. The computer, which is preferably called an electronic processing unit, then has the computer housing 6 according to FIG. 6, wherein the device 1 is fastened on at least the outer wall 21 of the computer housing 6 by means of its fan 2. The stator 4 is then placed onto a fluid inlet opening (not shown) in the outer wall.

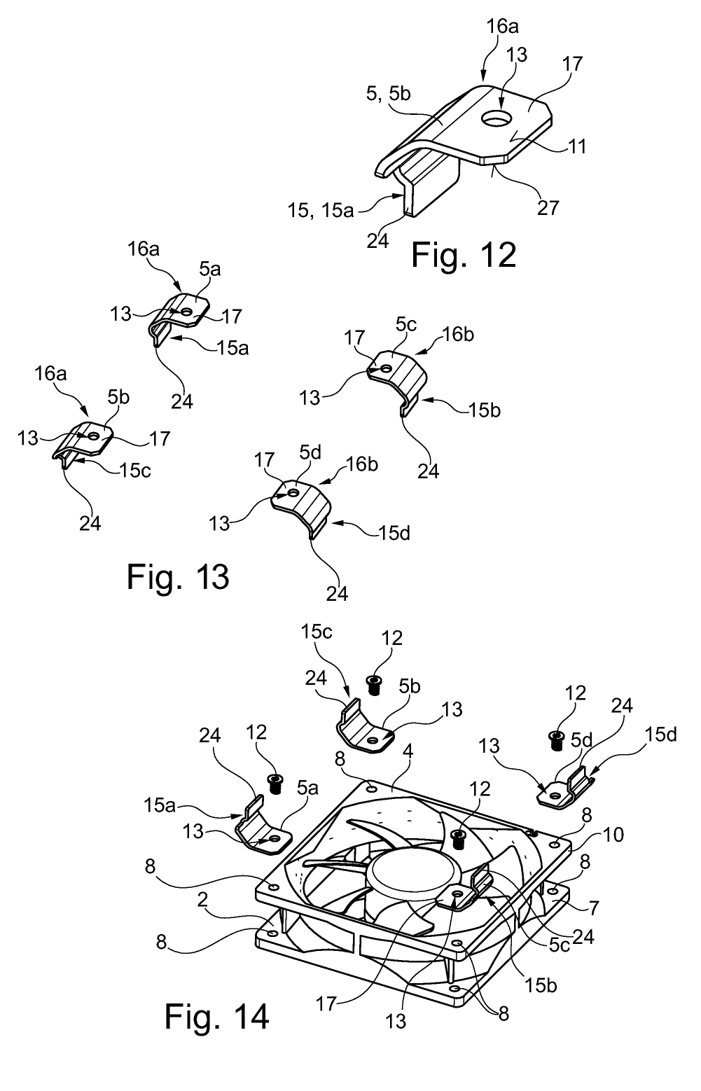

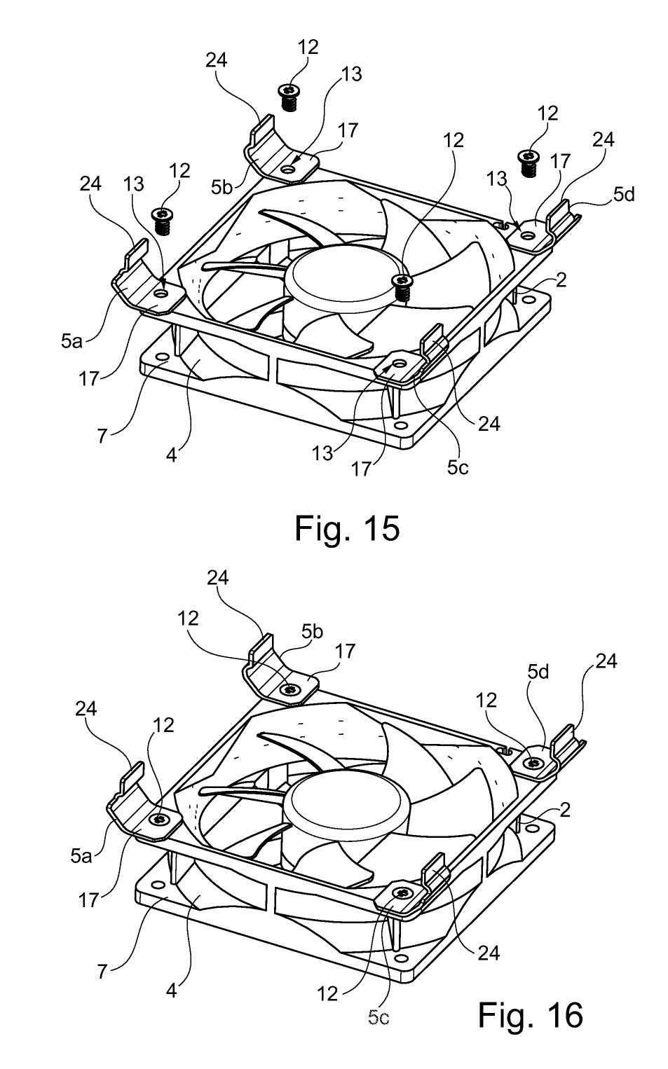

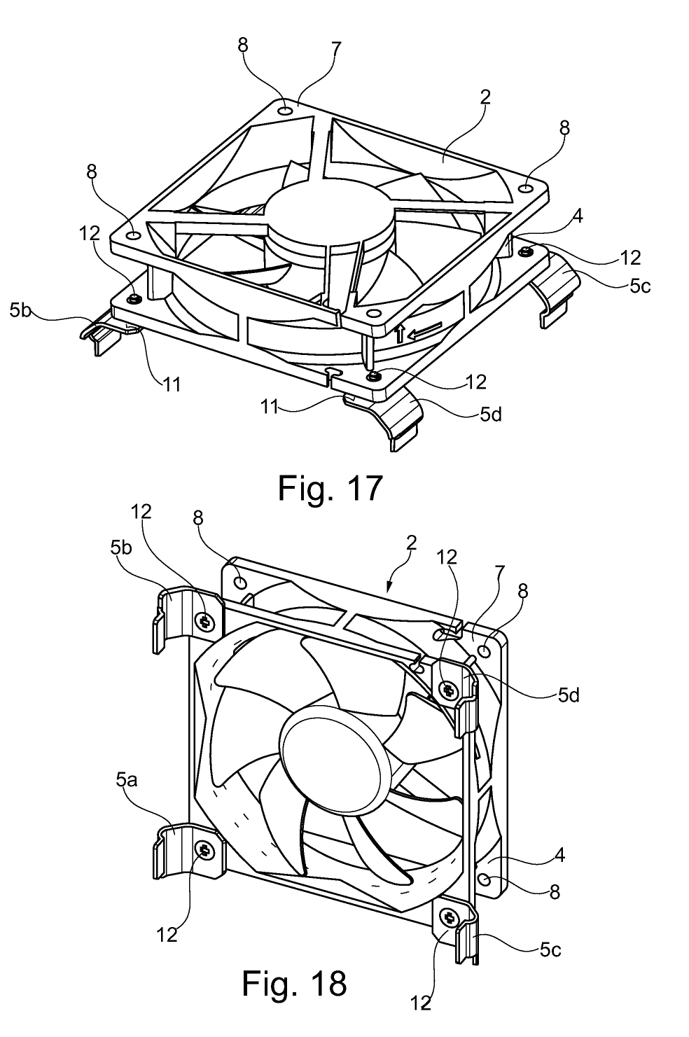

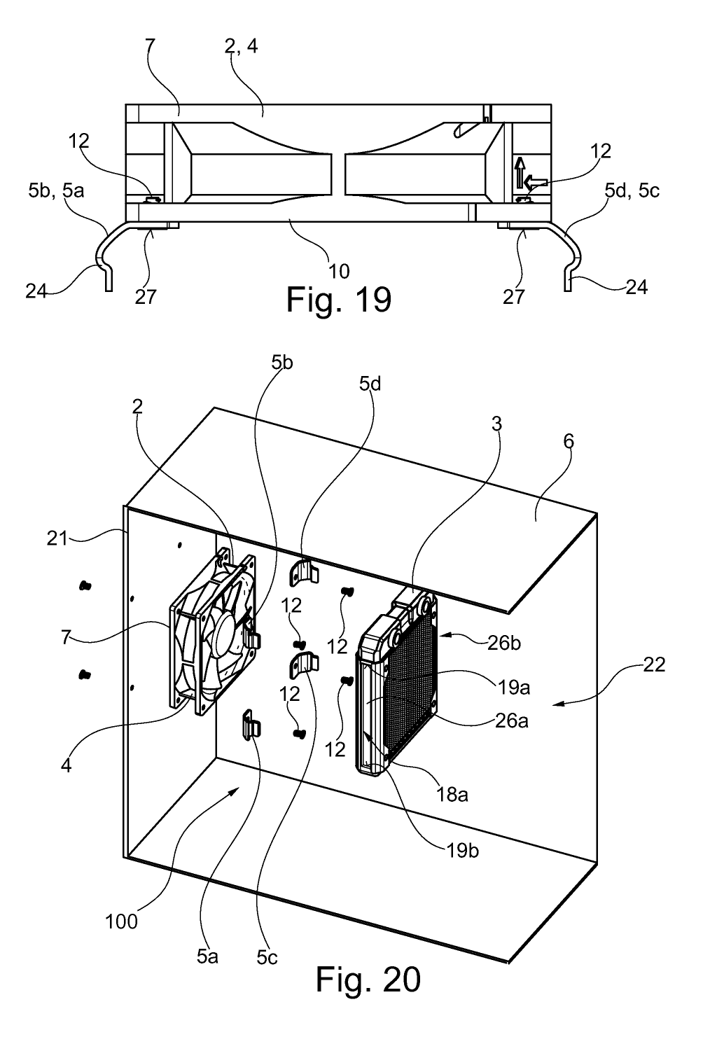

With reference now to FIGS. 12-21, a fan/clasp element pre-assembly of a device 100 is described in accordance with another embodiment of the invention. Other features of the fan/clasp element pre-assembly as well as device 100 generally correspond with those of the device 1 and are provided with matching reference numerals. In particular, the single clasp element 5 of the device 1 is replaced by a plurality of clasp elements 5, namely by four clasp elements 5.

As shown in FIG. 12, each clasp element 5 of the device 100 no longer has a fundamentally disk-shaped base section 17 but rather a mainly blade-shaped or plate-shaped base section 17. The base section 17 has a fastening means receiver 13 for receiving a fastening means 12. Each clasp element 5 also has the first contact surface 11, which is provided for contact on the second contact area 10 of the fan 2. The fan 2 is designed according to the first embodiment of the fan/clasp element pre-assembly or respectively the device 1. The base section 17 in turn rests with the first contact surface 11 in a planar manner on the second contact area 10 of the stator 4. Each fastening means 12 connects a clasp element 5 with the second contact area 10 of the stator 4 and thus also with the fan 2.

For the form-fitting hold of the heat exchanger 3 on the fan 2, four clasp elements 5, labeled below with the reference numbers 5a to 5d (FIG. 13), are provided in this embodiment. Each of the clasp elements 5a to 5d has a holding section 15a to 15d. Each of the holding sections 15a to 15d is in turn elastically deformable to form a snap catch 24.

The first clasp element 5a and the second clasp element 5b are arranged on the fan 2 on the side of a first lateral edge area 26a. The two first and second holding sections 15a and 15b, e.g. snap catches 24 of the clasp elements 5a and 5b are thereby in operative connection with the first lateral edge area 26a. In particular, the two snap catches 24 of the clasp elements 5a and 5b engage into the first recess 18a of the heat exchanger 3.

The two other clasp elements, i.e. the third clasp element 5c and the fourth clasp element 5d are arranged on the fan 2 and relative to the heat exchanger 3 such that they, with their third and fourth holding sections 15c and 15d and snap catches 24, surround the heat exchanger 3 in a form-fitting manner on a second lateral edge area 26b. Each snap catch 24 of the two clasp elements 5c and 5d is engaged or snapped into the second recess 18b on the heat exchanger 3.

As a result, the two first and second clasp elements 5a and 5b are in operative connection with the first lateral edge area 26a, the third and fourth clasp elements 5c and 5d with the second lateral edge area 26b. The clasp elements 5a and 5b or respectively 5c and 5d that are each assigned to a lateral edge area 26a or 26b are built similarly. FIG. 12 depicts the structure of the second clasp element 5b, but also exemplarily depicts the structure of clasp elements 5a, 5c and 5d.

The snap catches 24 or holding sections 15a to 15d of the four clasp elements 5a-d are locked into the respective recess 18a or respectively 18b such that they rest respectively with one side on one of the stop edges 19a or respectively 19b. A form-fitting, loss-proof and firm hold of the heat exchanger 3 on the fan 2 is thereby realized.

As shown in FIG. 13, the clasp elements 5a to 5d may not all include an identical structure. For example the bore holes forming the fastening means receivers 13 may not be incorporated in the case of all four clasp elements 5b and 5c or respectively 5a and 5d at the same point on the base section 17. As such, the clasp elements 5b and 5c or respectively 5a and 5d may be designed with matching structure.

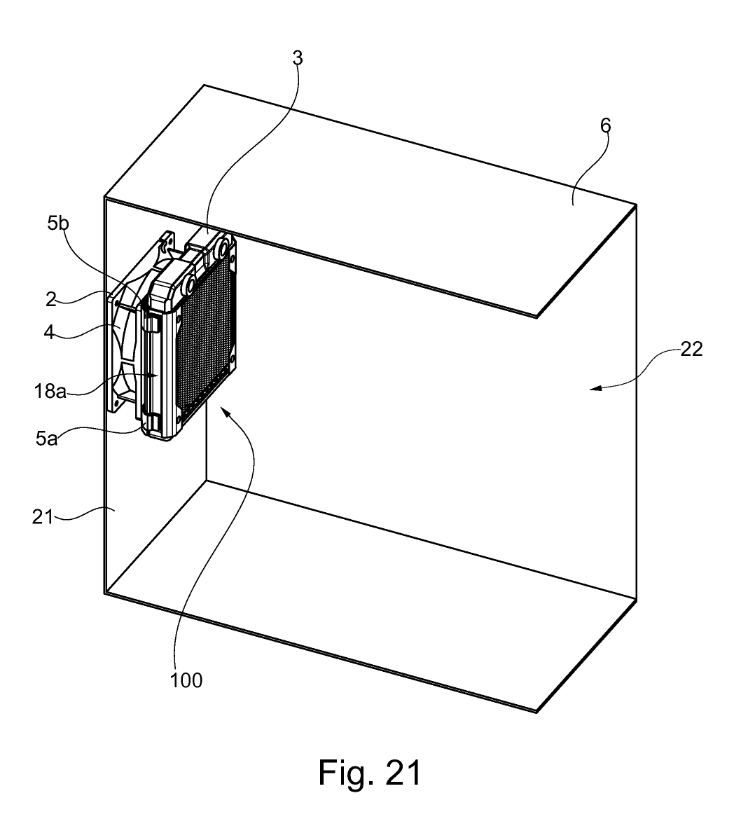

FIGS. 20 and 21 depict the computer housing 6, which is designed like the computer housing 6 described above with respect to the device 1. The device 100 integrated in the computer housing 6 of this further embodiment is mainly designed like the device 1 of the first embodiment, wherein in particular heat exchanger 3 and fan are built and function the same. The one clasp element 5 here is just replaced by the four clasp elements 5a to 5d. The form-fitting hold of the heat exchanger 3 by the clasp elements 5a to 5d is shown in FIG. 21.

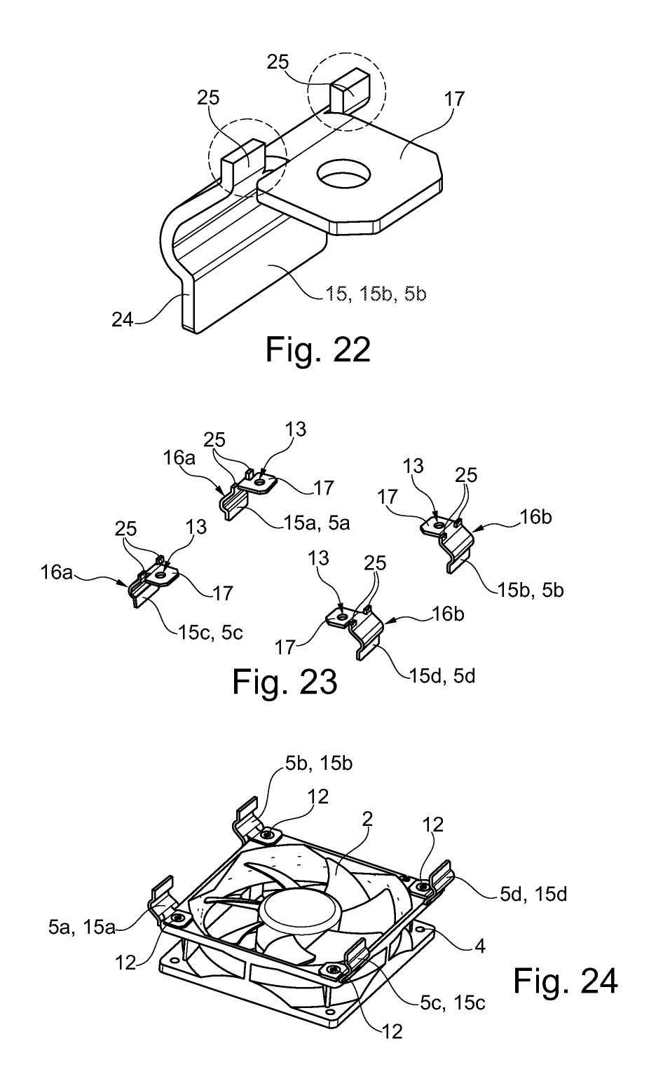

With reference now to FIG. 22-27, the fan/clasp element pre-assembly used in a device 200 is depicted in accordance with another embodiment of the invention. The device 200 is configured similarly to the device 100 depicted in FIGS. 12 to 21. The pre-assembly of the device 200 includes four individual clasp elements 5a to 5d, which are generally shaped like the clasp elements 5a to 5d shown in FIGS. 12 and 13. The fan/clasp element pre-assembly seen in FIG. 24 is thus designed and functions much like the pre-assembly shown in FIGS. 12 to 21.

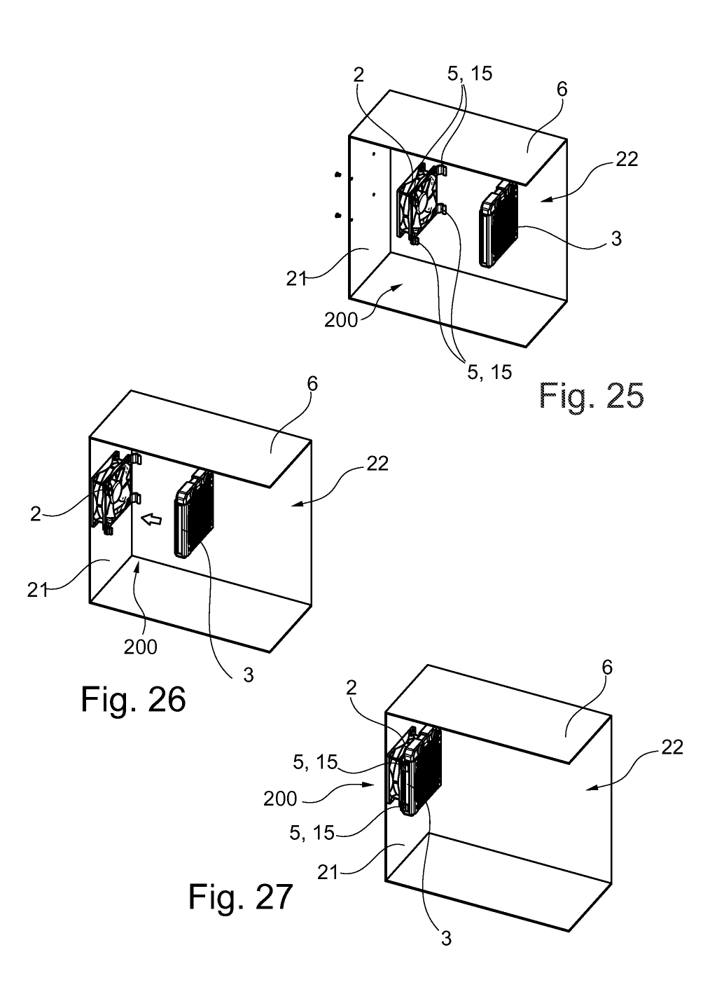

However, each of the four clasp elements 5a to 5d of the device 200 differs from those of the device 100 by two stop catches 25. These stop catches 25 extend from the base section 17, i.e. away from an imaginary plane, which forms/shapes the base section 17, in the vertical direction. These stop catches 25 are thereby shaped such that they are supported on the side of the fan 2, namely of the stator 4, in the installed state. This leads to an additional lock against rotation of the respective clasp element 5a to 5d around the fastening axis formed by the fastening means 12. The base section 17 in particular is thereby supported in a torque-proof manner on the stator 4, namely on the second contact area 10. FIGS. 25 to 27 depict installation of the device 200 in the computer housing 6 in a manner similar to that described previously above for the devices 1 and 100.

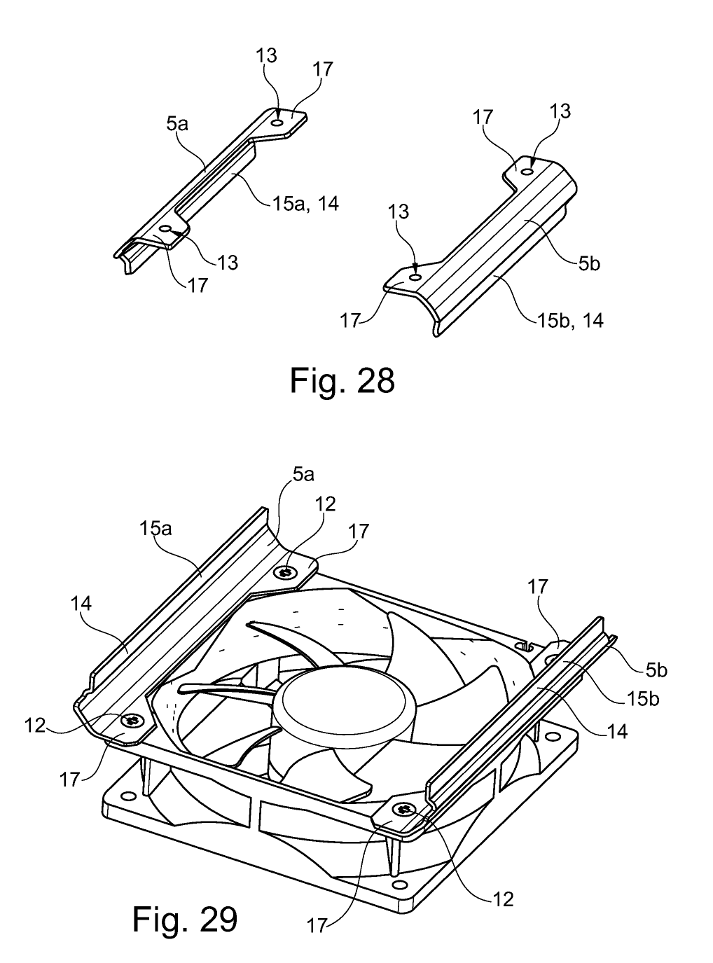

Referring now to FIGS. 28 and 32, a fan/clasp element pre-assembly of a device 300 is described in accordance with another embodiment of the invention. The device 300 is configured similarly to the device 1 but for the clasp element 5, which instead of comprising a one-piece clasp element is split into two clasp elements 5a and 5b designed substantially as mirror images of each other. The two clasp elements 5a and 5b may be identical and are assigned to a lateral edge area 26a or 26b of the heat exchanger 3 respectively.

Each clasp element 5a and 5b is built in a bar-shaped manner and has in particular a bar-shaped holding section 15a or respectively 15b, which is in turn also referred to as a snap bar 14. There are two fastening means 12 (screws) for fastening the clasp element on the stator 4 of the fan 2, as shown in FIG. 29, for each clasp element 5a and 5b. FIG. 28 shows fastening means receivers 13 provided on the base section 17, wherein the base section 17 is formed by two holding flaps arranged on respective end areas of the snap bar 14.

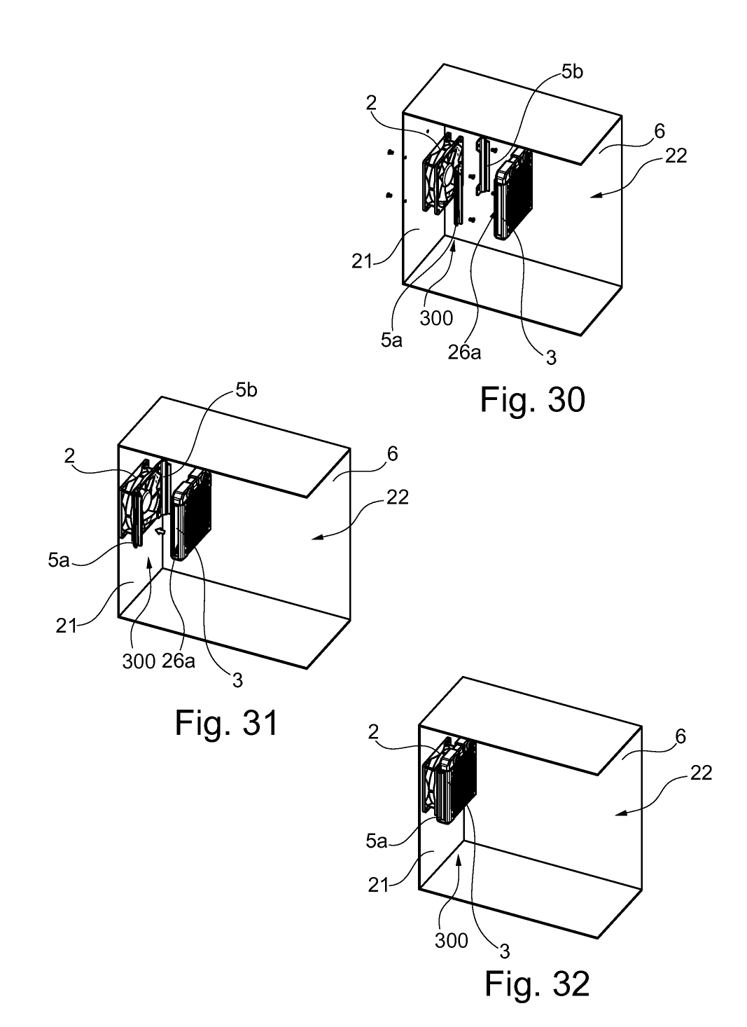

In FIGS. 30 to 32, installation of the device 300 in the computer housing 6 is depicted in accordance with an embodiment of the invention. The installation provides a form-fitting hold between the heat exchanger 3 and fan 2 or respectively the clasp elements 5a, 5b in the installed state (FIG. 32). The length of the first or second clasp element 5a or 5b is designed such that the length corresponds with the length of the recesses 18a, 18b in the heat exchanger 3. In their length, the snap bars 14 of the individual clasp elements 5a and 5b are thus mainly designed like the snap bars 14 of the clasp element 5 of the device 1, as depicted in FIG. 5.

Many different arrangements of the various components depicted, as well as components not shown, are possible without departing from the scope of the claims below. Embodiments of the technology have been described with the intent to be illustrative rather than restrictive. Alternative embodiments will become apparent to readers of this disclosure after and because of reading it. Alternative means of implementing the aforementioned can be completed without departing from the scope of the claims below. Identification of structures as being configured to perform a particular function in this disclosure and in the claims below is intended to be inclusive of structures and arrangements or designs thereof that are within the scope of this disclosure and readily identifiable by one of skill in the art and that can perform the particular function in a similar way. Certain features and sub-combinations are of utility and may be employed without reference to other features and sub-combinations and are contemplated within the scope of the claims.

What is claimed is:

1. A device for one or more of cooling and heating a computer housing interior, the device comprising:
a fan that creates a fluid flow, the fan including a stator that can be fixedly attached to a computer housing;
a heat exchanger influencing a temperature of the fluid flow and connected in a removable manner with the fan; and
a clasp element that holds the heat exchanger in a form-fitting manner on the fan.

2. The device of claim 1, wherein the clasp element has at least one elastically deformable holding section that engages a recess of the heat exchanger in a form-fitting manner.

3. The device of claim 2, wherein the at least one holding section includes one or more of a snap bar, a snap catch, and a snap finger configured to engage the recess of the heat exchanger.

4. The device of claim 1, wherein the clasp element has a disk-shaped or plate-shaped base section that is fastened to the fan stator.

5. The device of claim 4, wherein the clasp element includes at least two elastically deformable holding sections extending from the base section, the holding sections being disposed to engage opposite edges of the heat exchanger.

6. The device of claim 4, wherein the clasp element comprises a first clasp element and wherein the device includes a second clasp element configured substantially similarly to the first clasp element, the first and second clasp elements including a respective base section configured to couple to the fan along opposite edges of the fan stator, and each of the first and second clasp elements including an elastically deformable holding section extending from the respective base section, the holding sections being configured to engage a respective edge of the heat exchanger.

7. The device of claim 4, wherein holding section extends from the base section at an edge, and wherein the base section includes a stop catch extending from the edge but in an opposite direction to that of the holding sections, the base section configured to engage a first surface of the fan stator and the stop catch configured to engage a second surface of the fan stator.

8. The device of claim 1, wherein the clasp element is made of one or more of a metal, a sheet metal, and a plastic material.

9. The device of claim 1, wherein the fan stator has a fastening section that is prepared for fastening on the computer housing.

10. The device of claim 1, wherein the computer housing includes a fluid inlet opening and the fan is fastened on an outer wall of the computer housing in the area of the fluid inlet opening.

11. A housing for a computing device, comprising:
a fan fixedly coupled to a wall of the housing, the fan creating a fluid flow through an opening in the wall;
a heat exchanger influencing the temperature of the fluid flow and connected in a removable manner with the fan; and
a clasp element fixedly coupled to the fan and including an elastically deformable holding section that engages a recess on the heat exchanger, the clasp element removably engaging the heat exchanger in a form-fitting manner.

12. The housing of claim 11, wherein the heat exchanger is removable from the clasp element by hand and without tools.

13. A clasp element comprising:
a base section configured to be fastened to a fan stator; and
an elastically deformable holding section that is receivable in a recess on a heat exchanger in a form-fitting manner to removably couple the heat exchanger to the fan stator.

14. The clasp element of claim 13, wherein the clasp element includes at least two elastically deformable holding sections extending from the base section, the holding sections being disposed to engage opposite edges of the heat exchanger.

15. The clasp element of claim 13, wherein the base section is configured to couple to the fan stator along one edge of the stator, the holding section being configured to engage an edge of the heat exchanger.

16. The clasp element of claim 13, wherein holding section extends from the base section at an edge, and wherein the base section includes a stop catch extending from the edge but in an opposite direction to that of the holding sections, the base section configured to engage a first surface of the fan stator and the stop catch configured to engage a second surface of the fan stator.
